(19) United States
(12) Patent Application Publication
(10) Pub. No.: US 2024/0315086 A1
(43) Pub. Date: Sep. 19, 2024

(54) OLED PANEL WITH SEPARATE OVERHANGS

(71) Applicant: Applied Materials, Inc., Santa Clara, CA (US)

(72) Inventors: Chung-chia CHEN, Hsinchu City (TW); Ji Young CHOUNG, Hwaseong-si (KR); Yu-Hsin LIN, Zhubei City (TW); Jungmin LEE, Santa Clara, CA (US)

(21) Appl. No.: 18/601,566

(22) Filed: Mar. 11, 2024

Related U.S. Application Data
(60) Provisional application No. 63/506,272, filed on Jun. 5, 2023.
(60) Provisional application No. 63/490,613, filed on Mar. 16, 2023.

(51) Int. Cl. H10K 59/122; H10K 59/12; H10K 59/80

(52) U.S. Cl. CPC H10K 59/122; H10K 59/1201; H10K 59/873

(57) ABSTRACT

Embodiments described herein generally relate to a device. The device includes a substrate, and a plurality of sub-pixels. Each sub-pixel includes adjacent overhangs disposed over the substrate. Each overhang includes two or more overhang structures, an organic light emitting diode (OLED) material, and a cathode. The overhang structures include a first overhang defined by a first overhang structure outer extension of a second structure extending laterally past a first structure. The first structure is disposed over the substrate. The second structure is disposed over the first structure. The second structure of a first overhang structure is separated from the second structure of a second overhang structure by a structure gap. The OLED material is disposed over an anode. The cathode is disposed over the OLED material.

### CROSS-REFERENCE TO RELATED APPLICATIONS

This application claims benefit of U.S. provisional patent application Ser. No. 63/506,272, filed Jun. 5, 2023 and U.S. provisional patent application Ser. No. 63/490,613, filed Mar. 16, 2023, both of which are herein incorporated by reference.

### BACKGROUND

### Field

Embodiments described herein generally relate to a display. More specifically, embodiments described herein relate to sub-pixel circuits and methods of forming sub-pixel circuits that may be utilized in a display such as an organic light-emitting diode (OLED) display.

### Description of the Related Art

Input devices including display devices may be used in a variety of electronic systems. An organic light-emitting diode (OLED) is a light-emitting diode (LED) in which the emissive electroluminescent layer is a film of an organic compound that emits light in response to an electric current. OLED devices are classified as bottom emission devices if light emitted passes through the transparent or semi-transparent bottom electrode and substrate on which the panel was manufactured. Top emission devices are classified based on whether or not the light emitted from the OLED device exits through the lid that is added following the fabrication of the device. OLEDs are used to create display devices in many electronics today. Today's electronics manufacturers are pushing these display devices to shrink in size while providing higher resolution than just a few years ago.

OLED pixel patterning is currently based on a process that restricts panel size, pixel resolution, and substrate size. Rather than utilizing a fine metal mask, photo lithography should be used to pattern pixels. Currently, OLED pixel patterning requires lifting off organic material after the patterning process. When lifted off, the organic material leaves behind a particle issue that disrupts OLED performance. Accordingly, what is needed in the art are sub-pixel circuits and methods of forming sub-pixel circuits to increase pixel-per-inch and provide improved OLED performance.

### SUMMARY

A device is shown and described herein. The device includes a substrate and a plurality of sub-pixels. Each sub-pixel includes adjacent overhangs disposed over the substrate. Each overhang includes two or more overhang structures, an organic light emitting diode (OLED) material, and a cathode. The overhang structures include a first overhang defined by a first overhang structure outer extension of a second structure extending laterally past a first structure. The first structure is disposed over the substrate. The second structure is disposed over the first structure. The second structure of a first overhang structure is separated from the second structure of a second overhang structure by a structure gap. The OLED material is disposed over an anode. The cathode is disposed over the OLED material.

A method of forming a device is shown and described herein. The method includes depositing a first structure layer and a second structure layer over a substrate; depositing and patterning a plurality of first resists over the second structure layer; removing a portion of the second structure layer and the first structure layer to form an overhang, the overhang having two or more overhang structures separated by a structure gap comprising a second structure formed from the second structure layer disposed over a first structure formed from the first structure layer; depositing an organic light emitting diode (OLED) material, a cathode, and an encapsulation layer of a first sub-pixel over the overhang; depositing and patterning a second resist over the first sub-pixel; and removing a portion of the encapsulation layer, the cathode, and the OLED material.

A device is shown and described herein. The device includes a substrate and a plurality of sub-pixels. Each sub-pixel includes adjacent overhangs disposed over the substrate. Each overhang includes two or more overhang structures, an organic light emitting diode (OLED) material, and a cathode. The overhang structures include a first overhang and a second overhang. The first overhang is defined by a first overhang structure outer extension of a second structure extending laterally past an upper surface and an outer sidewall of a first structure. The second overhang is defined by a first overhang structure inner extension extending laterally past the upper surface and an inner sidewall of the first structure. The first structure is disposed over the substrate. The second structure disposed over the first structure. The first overhang structure is separated from the second overhang structure by a structure gap. The OLED material is disposed over an anode. The cathode is disposed over the OLED material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a schematic, cross-sectional view of a sub-pixel circuit at section line 1A-1A, according to embodiments.

FIG. 1B is a schematic, cross-sectional view of an overhang structure of a sub-pixel circuit at section line 1B-1B, according to embodiments.

FIG. 1C is a schematic, cross-sectional view of a sub-pixel circuit at section line 1A-1A, according to embodiments.

FIG. 1D is a schematic, cross-sectional view of an overhang structure of a sub-pixel circuit at section line 1B-1B, according to embodiments.

FIG. 1E is a schematic, top sectional view of the sub-pixel circuit at section line 1C-1C, according to embodiments.

FIG. 2 is a flow diagram of a method for forming a sub-pixel circuit, according to embodiments.

FIGS. 3A-3M are schematic, cross-sectional views of the substrate during a method for forming the sub-pixel circuit according embodiments.

FIGS. 4A-4D are schematic, cross-sectional views of the overhang according embodiments.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments described herein generally relate to a display. More specifically, embodiments described herein relate to sub-pixel circuits and methods of forming sub-pixel circuits that may be utilized in a display such as an organic light-emitting diode (OLED) display. In various embodiments, the sub-pixels employ advanced overhang structures to improve functionality of the display.

Each of the embodiments described herein of the sub-pixel circuit include a plurality of sub-pixels with each of the sub-pixels defined by adjacent overhang structures that are permanent to the sub-pixel circuit. While the Figures depict two sub-pixels with each sub-pixel defined by adjacent overhang structures, the sub-pixel circuit of the embodiments described herein include a plurality of sub-pixels, such as two or more sub-pixels. Each sub-pixel has OLED materials configured to emit a white, red, green, blue or other color light when energized. E.g., the OLED materials of a first sub-pixel emits a red light when energized, the OLED materials of a second sub-pixel emits a green light when energized, and the OLED materials of a third sub-pixel emits a blue light when energized.

The overhangs are permanent to the sub-pixel circuit. The overhangs include two or more overhang structures, e.g., at least a first overhang structure and a second overhang structure. Each overhang structure includes at least a second structure disposed over a first structure. The adjacent overhang structures defining each sub-pixel of the sub-pixel circuit of the display provide for formation of the sub-pixel circuit using evaporation deposition and provide for the overhang structures to remain in place after the sub-pixel circuit is formed. Evaporation deposition is utilized for deposition of OLED materials (including a hole injection layer (HIL), a hole transport layer (HTL), an emissive layer (EML), and an electron transport layer (ETL)) and cathode. In some instances, an encapsulation layer may be disposed via evaporation deposition. In embodiments including one or more capping layers, the capping layers are disposed between the cathode and the encapsulation layer. The encapsulation layer of a respective sub-pixel is disposed over the cathode. The overhangs and the evaporation angle set by the evaporation source define the deposition angles, i.e., the overhangs provide for a shadowing effect during evaporation deposition with the evaporation angle set by the evaporation source.

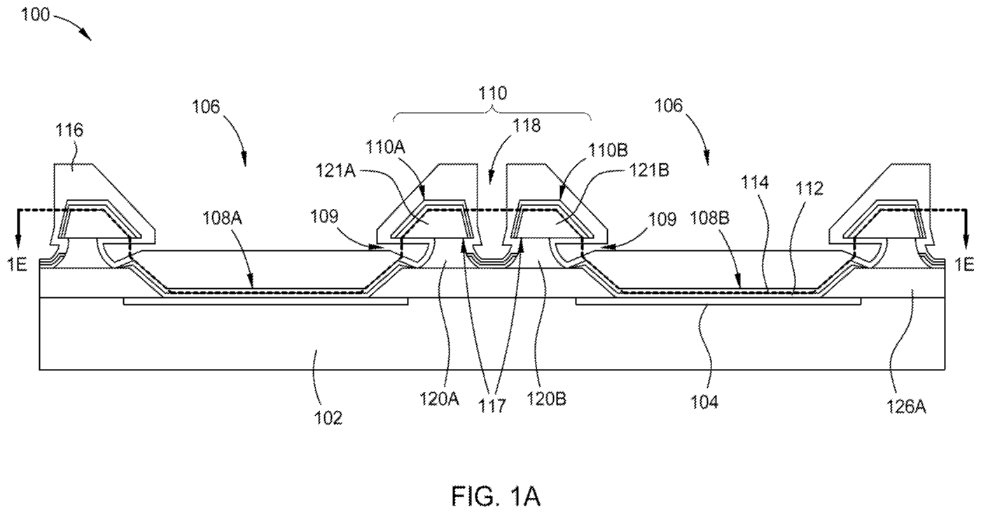

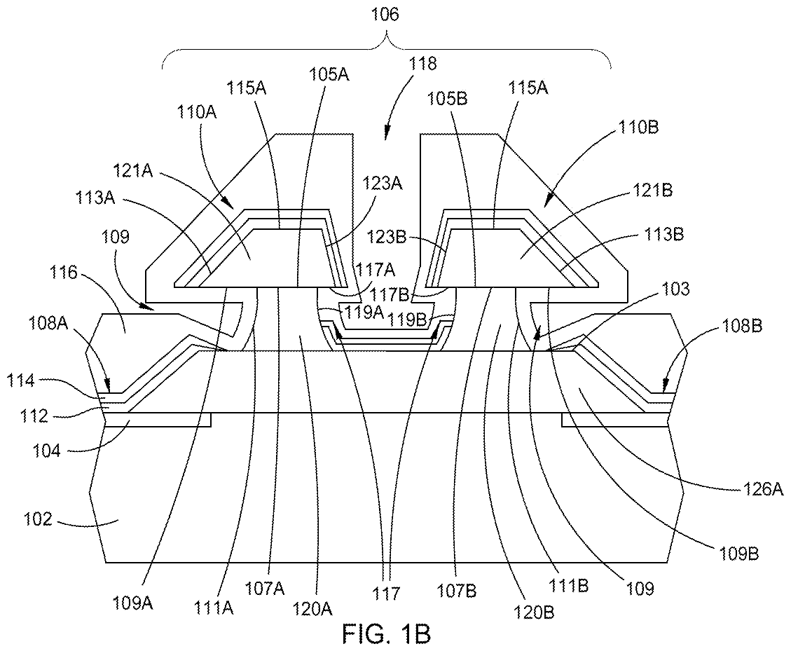

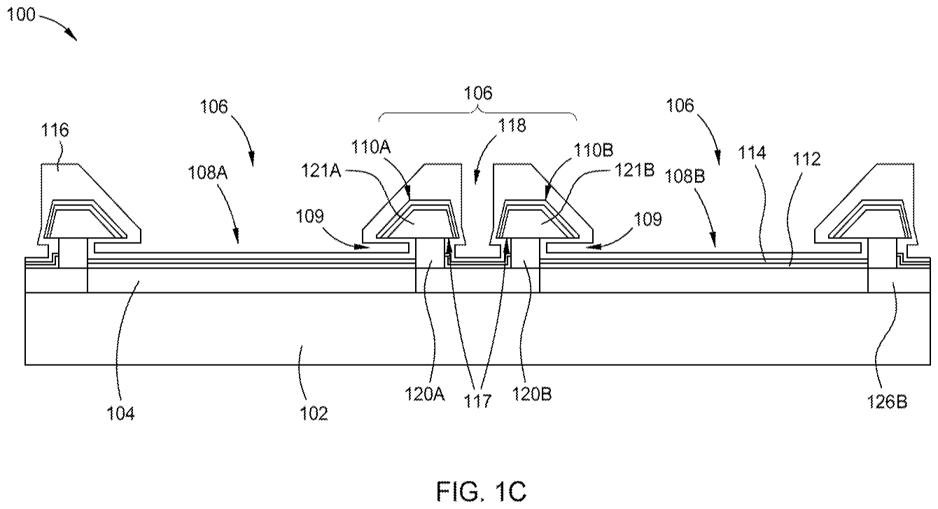

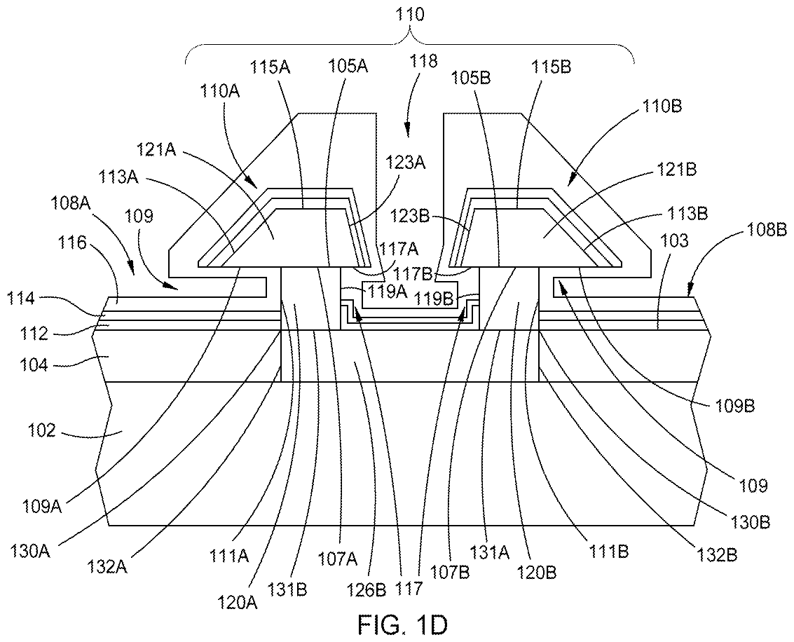

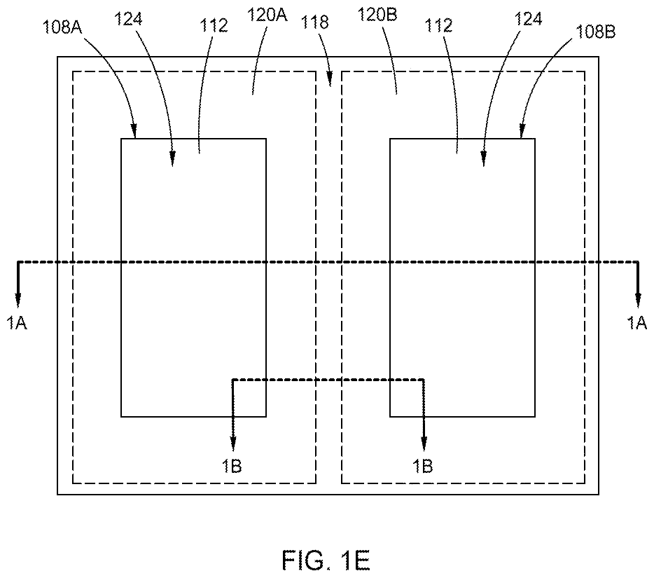

FIG. 1A is a schematic, cross-sectional view of a first sub-pixel circuit 100A. The cross-sectional view of FIG. 1A is taken along section line 1A-1A of FIG. 1E. FIG. 1B is a schematic, cross-sectional view of an overhang structure 110 of the first sub-pixel circuit 100A. The cross-sectional view of FIG. 1B is taken along section line 1B-1B of FIG. 1E. FIG. 1E is a schematic, top sectional view of the first sub-pixel 100A along section line 1E-1E.

The first sub-pixel circuit 100A includes a substrate 102. Metal-containing layers 104 (e.g., anodes) may be patterned on the substrate 102 and are defined by adjacent pixel structures (PS) 126A disposed on the substrate 102. In one embodiment, the PS 126A are disposed on the substrate 102. In one embodiment, the metal-containing layers 104 are pre-patterned on the substrate 102. E.g., the substrate 102 is pre-patterned with metal-containing layers 104 of indium tin oxide (ITO). The metal-containing layers 104 are configured to operate as anodes of respective sub-pixels. In one embodiment, the metal-containing layer 104 is a layer stack of a first transparent conductive oxide (TCO) layer, a second metal-containing layer disposed on the first TCO layer, and a third TCO layer disposed on the second metal-containing layer. The metal-containing layers 104 include, but are not limited to, chromium, titanium, gold, silver, copper, aluminum, ITO, a combination thereof, or other suitably conductive materials.

The plurality of PS 126A are disposed over the substrate 102. The PS 126A include one of an organic material, an organic material with an inorganic coating disposed thereover, or an inorganic material. The organic material of the PS 126A includes, but is not limited to, polyimides. The inorganic material of the PS 126A includes, but is not limited to, silicon oxide (SiO₂), silicon nitride (Si₃N₄), silicon oxynitride (Si₂N₂O), magnesium fluoride (MgF₂), or combinations thereof. Adjacent PS 126A define a respective sub-pixel and expose the anode (i.e., metal-containing layer 104) of the respective first sub-pixel circuit 100A.

The first sub-pixel circuit 100A has a plurality of sub-pixels 106 including at least a first sub-pixel 108A and a second sub-pixel 108B. While the Figures depict the first sub-pixel 108A and the second sub-pixel 108B, the first sub-pixel circuit 100A of the embodiments described herein may include two or more sub-pixels 106, such as a third and a fourth sub-pixel. Each sub-pixel 106 has OLED materials configured to emit a white, red, green, blue or other color light when energized. E.g., the OLED materials of the first sub-pixel 108A emits a red light when energized, the OLED materials of the second sub-pixel 108B emits a green light when energized, the OLED materials of a third sub-pixel emits a blue light when energized, and the OLED materials of a fourth sub-pixel emits another color light when energized.

Each sub-pixel 106 includes overhangs 110. The overhangs 110 are permanent to the first sub-pixel circuit 100A. The overhangs 110 further define each sub-pixel 106 of the first sub-pixel circuit 100A. Each overhang 110 includes two or more overhang structures, such as first overhang structure 110A and second overhang structures 110B. The overhang structures (e.g., first overhang structure 110A and second overhang structures 110B) are separated by a gap 118. The first overhang structure 110A includes first structure 120A and a second structure 121A. The second structure 121A is disposed over the first structure 120A. The second overhang structure 110B includes first structure 120B and a second structure 121B. The second structure 121B is disposed over the first structure 120B. The first overhang structures 110A and second overhang structure 110B includes first overhang 109 and second overhang 117. The first overhangs 109 are defined by a first overhang extension 109A of the second structure 121A extending laterally past an upper surface 105A of a first structure 120A and a first overhang extension 109B of the second structure 121B extending laterally past an upper surface 105B of a first structure 120B. In some embodiments, the first overhang extension 109A and first overhang extension 109B extend laterally past an outer sidewall 111A and an outer sidewall 111B of the first structure 120A and first structure 120B, respectively.

The second overhangs 117 are defined by a second overhang extension 117A of the second structure 121A extending laterally past an upper surface 105A of a first structure 120A and a second overhang extension 117B of the second structure 121B extending laterally past an upper surface 105B of a first structure 120B. In some embodiments, the first overhang extension 117A and first overhang extension 117B extend laterally past an inner sidewall 119A and an inner sidewall 119B of the first structure 120A and first structure 120B, respectively.

In one embodiment, the second structure 121A and second structure 121B include a non-conductive inorganic material and the first structure 120A and first structure 120B include a conductive inorganic material. The conductive materials of the first structure 120A, 120B include aluminum (Al), aluminum neodymium (AlNd), molybdenum (Mo), molybdenum tungsten (MoW), copper (Cu), titanium (Ti), or combinations thereof. The inorganic materials of the second structure 121A and second structure 121B include silicon nitride (Si₃N₄), silicon oxide (SiO₂), silicon oxynitride (Si₂N₂O), or combinations thereof. The first overhang structure 110A and second overhang structure 110B are able to remain in place, i.e., are permanent. Thus, organic material from lifted off the overhang 110 that disrupt OLED performance would not be left behind. Eliminating the need for a lift-off procedure increases throughput.

In one embodiment, the first structure 120A and first structure 120B include a metal containing material. In one example, the metal-containing material is a transparent conductive oxide (TCO) material. The TCO material includes, but is not limited to, indium zinc oxide (IZO), indium tin oxide (ITO), indium gallium zinc oxide (IGZO), or combinations thereof. In another embodiment, the first structure 120A, first structure 120B, the second structure 121A, and the second structure 121B include a conductive material.

The first overhang 109 of the first overhang structure 110A and the first overhang 109 of the second overhang structure 110B are defined by a first overhang extension 109A and first overhang extension 109B, respectively. The second overhang 117 of the first overhang structure 110A and the second overhang 117 of the second overhang structure 110B are defined by a second overhang extension 117A and second overhang extension 117B, respectively. At least a bottom surface 107A of the second structure 121A and a bottom surface 107B of the second structure 121B are wider than the upper surface 105 of a first structure 120A and first structure 120B, respectively, to form the first overhang extension 109A, first overhang extension 109B, second overhang extension 117A, and second overhang extension 117B.

The first overhang extension 109A and first overhang extension 109B forms the first overhangs 109 and the second overhang extension 117A and second overhang extension 117B forms the second overhang 117, and allows for the second structure 121A and second structure 121B to shadow the first structure 120A and 120B, respectively. The shadowing of the first overhang 109 and the second overhang 117 provides for evaporation deposition of OLED materials 112 and a cathode 114. The OLED materials 112 may include one or more of a HIL, a HTL, an EML, and an ETL. The OLED material is disposed over and in contact with the metal-containing layer 104. The OLED material 112 is disposed under adjacent first overhang 109 and adjacent second overhang 117. In some embodiments, the OLED material 112 is disposed over outer sidewall 111A of the first structure 120A, the outer sidewall 111B of the first structure 120B, the inner sidewall 119A of the first structure 120A, and the inner sidewall 119B of the first structures 120B. In some embodiments, the OLED material 1121 is disposed over an outer sidewall 113A of the second structure 121A, an outer sidewall 113B of the second structure 121B, an inner sidewall 123A of the second structure 121A, and an inner sidewall 123B of the second structure 121B.

The cathode 114 includes a conductive material, such as a metal. E.g., the cathode 114 includes, but is not limited to, silver, magnesium, chromium, titanium, aluminum, ITO, or a combination thereof. The cathode 114 is disposed over the OLED material 112. In some embodiments, the cathode 114 is disposed over outer sidewall 111A of the first structure 120A, the outer sidewall 111B of the first structure 120B, the inner sidewall 119A of the first structure 120A, and the inner sidewall 119B of the first structures 120B. In some embodiments, the cathode 114 is disposed over an outer sidewall 113A of the second structure 121A, an outer sidewall 113B of the second structure 121B, an inner sidewall 123A of the second structure 121A, and an inner sidewall 123B of the second structure 121B.

Each sub-pixel 106 includes an encapsulation layer 116. The encapsulation layer 116 may be or may correspond to a local passivation layer. The encapsulation layer 116 of a respective sub-pixel is disposed over the cathode 114 (and OLED material 112) with the encapsulation layer 116 extending under at least a portion of each of the first overhangs 109 and the second overhangs 117. The encapsulation layer 116 may be disposed along the sidewalls 111A, 111B, 113A, 113B, 119A, 119B, 123A, 123B. In some embodiments, the encapsulation layer 116 is disposed over an upper surface 115A of the second structure 121A and an upper surface 115B of the second structure 121B. The encapsulation layer 116 includes the non-conductive inorganic material, such as the silicon-containing material. The silicon-containing material may include Si₃N₄ containing materials.

Disposing the OLED material 112, the cathode 114, and the encapsulation layer 116 over the sidewalls 111A, 111B, 113A, 113B, 119A, 119B, 123A, 123B encapsulates the overhang structures 110A, 110B of the overhangs 110. The encapsulation prevents the creation of moisture invasion paths during fabrication. Less invasion paths decrease the likelihood of moisture invasion, thus preventing deterioration of the sub-pixel circuit 100.

In embodiments including one or more capping layers, the capping layers are disposed between the cathode 114 and the encapsulation layer 116. E.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition.

In another embodiment, the first sub-pixel circuit 100A further includes at least a global passivation layer 120 disposed over the overhang structure 110 and the encapsulation layer 116. In yet another embodiment, the sub-pixel includes an intermediate passivation layer disposed over the overhang structures 110 of each of the sub-pixels 106, and disposed between the encapsulation layer 116 and the global passivation layer 120.

FIG. 1C is a schematic, cross-sectional view of a second sub-pixel circuit 100B according to embodiments. FIG. 1D is a schematic, cross-sectional view of the second sub-pixel circuit 100B according to embodiments. The second sub-pixel circuit 100B includes a substrate 102. A base layer 125 may be patterned over the substrate 102. The base layer 125 includes, but is not limited to, a CMOS layer. Metal-containing layers 104 (e.g., anodes) may be patterned on the base layer 125 and are defined by adjacent pixel structures (PS) 126B disposed on the substrate 102. In one embodiment, the metal-containing layer 104 are pre-patterned on the base layer 125. E.g., the base layer 125 is pre-patterned with metal-containing layer 104 of indium tin oxide (ITO). The metal-containing layer 104 may be disposed on the substrate 102. The metal-containing layer 104 is configured to operate as an anode of respective sub-pixels. In one embodiment, the metal-containing layer 104 is a layer stack of a first transparent conductive oxide (TCO) layer, a second metal-containing layer disposed on the first TCO layer, and a third TCO layer disposed on the second metal-containing layer. The metal-containing layer 104 include, but are not limited to, chromium, titanium, gold, silver, copper, aluminum, ITO, a combination thereof, or other suitably conductive materials.

The PS 126B are disposed over the substrate 102. The PS 126B may be disposed on the base layer 125. The PS 126B include one of an organic material, an organic material with an inorganic coating disposed thereover, or an inorganic material. The organic material of the PS 126B includes, but is not limited to, polyimides. The inorganic material of the PS 126B includes, but is not limited to, silicon oxide (SiO₂), silicon nitride (Si₃N₄), silicon oxynitride (Si₂N₂O), magnesium fluoride (MgF₂), or combinations thereof. Adjacent PS 126B define a respective sub-pixel and expose the metal-containing layer 104 of the respective second sub-pixel circuit 100B.

The second sub-pixel circuit 100B has a plurality of sub-pixel lines (e.g., first sub-pixel line 106A and second sub-pixel line 106B). The sub-pixel lines are adjacent to each other along the pixel plane. Each sub-pixel line includes at least two sub-pixels. E.g., the first sub-pixel line 106A includes a first sub-pixel 108A and a second sub-pixel (not shown) and the second sub-pixel line 106B includes a third sub-pixel 108C and a fourth sub-pixel (not shown). While FIG. 1A depicts the first sub-pixel line 106A and the second sub-pixel line 106B, the second sub-pixel circuit 100B of the embodiments described herein may include two or more sub-pixel lines, such as a third sub-pixel line and a fourth sub-pixel. Each sub-pixel line has OLED materials configured to emit a white, red, green, blue or other color light when energized. E.g., the OLED materials of the first sub-pixel line 106A emits a red light when energized, the OLED materials of the second sub-pixel line 106B emits a green light when energized, the OLED materials of a third sub-pixel line emits a blue light when energized, and the OLED materials of a fourth sub-pixel emits another color light when energized. The OLED materials within a pixel line may be configured to emit the same color light when energized. E.g., the OLED materials of the first sub-pixel 108A and the second sub-pixel of the first sub-pixel line 106A emit a red light when energized and the OLED materials of the third sub-pixel 108C and the fourth sub-pixel of the second sub-pixel line 106B emit a green light when energized.

Each sub-pixel line includes adjacent overhangs 110, with adjacent sub-pixel lines sharing the adjacent overhangs 110. The overhangs 110 are permanent to the second sub-pixel circuit 100B. The overhangs 110 further define each sub-pixel line of the second sub-pixel circuit 100B. Each overhang 110 includes two or more overhang structures, such as first overhang structure 110A and second overhang structures 110B. The overhang structures (e.g., first overhang structure 110A and second overhang structures 110B) are separated by a gap 118. The first overhang structure 110A includes first structure 120A and a second structure 121A. The second structure 121A is disposed over the first structure 120A.

The second overhang structure 110B includes first structure 120B and a second structure 121B. The second structure 121B is disposed over the first structure 120B. The first overhang structures 110A and second overhang structure 110B includes first overhang 109 and second overhang 117. The first overhangs 109 are defined by a first overhang extension 109A (as shown in FIG. 11B) of the second structure 121A extending laterally past an upper surface 105A of a first structure 120A and a first overhang extension 109B (as shown in FIG. 1B) of the second structure 121B extending laterally past an upper surface 105B of a first structure 120B. In some embodiments, the first overhang extension 109A and first overhang extension 109B extend laterally past an outer sidewall 111A and an outer sidewall 111B of the first structure 120A and first structure 120B, respectively. A first endpoint 130A of a bottom surface 131A of the first structure 120A may extend to or past a first edge 132A of the PS 126B. A first endpoint 130B of a bottom surface 131B of the first structure 120B may extend to or past a second edge 132B of the PS 126B.

The second structure 121A and the second structure 121B may also be disposed over an intermediate structure. The intermediate structure may be disposed over the upper surface 105A of the first structure 120A for the first overhang structure 110A and over the upper surface 105B of the first structure 120B for the first overhang structure 110B. The intermediate structure may be a seed layer or an adhesion layer. The seed layer functions as a current path for the second sub-pixel circuit 100B. The seed layer may include a titanium (Ti) material. The adhesion promotion layer improves adhesion between the first structure 120A, 120B and the second structure 121A, 121B. The adhesion layer may include a chromium (Cr) material.

The second overhangs 117 are defined by a second overhang extension 117A (as shown in FIG. 1B) of the second structure 121A extending laterally past an upper surface 105A of a first structure 120A and a second overhang extension 117B (as shown in FIG. 1B) of the second structure 121B extending laterally past an upper surface 105B of a first structure 120B. In some embodiments, the first overhang extension 109A and second overhang extension 117B extend laterally past an inner sidewall 119A and an inner sidewall 119B of the first structure 120A and first structure 120B, respectively.

In one embodiment, the second structure 121A and second structure 121B includes a conductive inorganic material and the first structure 120A and first structure 120B include a non-conductive inorganic material. The conductive materials of the second structure 121A and second structure 121B include a copper (Cu), chromium (Cr), aluminum (AI), aluminum neodymium (AlNd), molybdenum (Mo), molybdenum tungsten (MoW), titanium (Ti), or combinations thereof. The non-conductive materials of the first structure 120A and first structure 120B include amorphous silicon (a-Si), silicon nitride (Si₃N₄), silicon oxide (SiO₂), silicon oxynitride (Si₂N₂O), or combinations thereof. The overhangs 110 are able to remain in place, i.e., are permanent.

The first overhang 109 of the first overhang structure 110A and the first overhang 109 of the second overhang structure 110B are defined by a first overhang extension 109A and first overhang extension 109B, respectively. The second overhang 117 of the first overhang structure 110A and the second overhang 117 of the second overhang structure 110B are defined by a second overhang extension 117A and second overhang extension 117B, respectively. At least a bottom surface 107A of the second structure 121A and a bottom surface 107B of the second structure 121B are wider than the upper surface 105 of a first structure 120A and first structure 120B, respectively, to form the first overhang extension 109A, first overhang extension 109B, second overhang extension 117A, and second overhang extension 117B.

The first overhang extension 109A first overhang extension 109B, second overhang extension 117A, and second overhang extension 117B forms the first overhang 109 and second overhang 117, respectively, and allows for the second structure 121A and second structure 121B to shadow the first structure 120A and 120B, respectively. The shadowing of the first overhang 109 and the second overhang 117 provides for evaporation deposition of OLED materials 112 and a cathode 114. The OLED materials 112 may include one or more of a HIL, a HTL, an EML, and an ETL. The OLED material is disposed over and in contact with the metal-containing layer 104. The OLED material 112 is disposed under adjacent first overhang 109 and adjacent second overhang 117. In some embodiments, the OLED material 112 is disposed over outer sidewall 111A of the first structure 120A, the outer sidewall 111B of the first structure 120B, the inner sidewall 119A of the first structure 120A, and the inner sidewall 119B of the first structures 120B. In some embodiments, the OLED material 1121 is disposed over an outer sidewall 113A of the second structure 121A, an outer sidewall 113B of the second structure 121B, an inner sidewall 123A of the second structure 121A, and an inner sidewall 123B of the second structure 121B. In still other embodiments, the OLED material 112 ends on the outer sidewall 111A of the first structure 120A, the outer sidewall 111B of the first structure 120B, the inner sidewall 119A of the first structure 120A, and the inner sidewall 119B of the first structures 120B, i.e., is not disposed over the outer sidewall 113A of the second structure 121A, an outer sidewall 113B of the second structure 121B, an inner sidewall 123A of the second structure 121A, and an inner sidewall 123B of the second structure 121B.

The cathode 114 includes a conductive material, such as a metal. E.g., the cathode 114 includes, but is not limited to, silver, magnesium, chromium, titanium, aluminum, ITO, or a combination thereof. The cathode 114 is disposed over the OLED material 112. In some embodiments, the cathode 114 is disposed over outer sidewall 111A of the first structure 120A, the outer sidewall 111B of the first structure 120B, the inner sidewall 119A of the first structure 120A, and the inner sidewall 119B of the first structures 120B. In some embodiments, the cathode 114 is disposed over an outer sidewall 113A of the second structure 121A, an outer sidewall 113B of the second structure 121B, an inner sidewall 123A of the second structure 121A, and an inner sidewall 123B of the second structure 121B. In still other embodiments, the cathode 114 ends on the outer sidewall 111A of the first structure 120A, the outer sidewall 111B of the first structure 120B, the inner sidewall 119A of the first structure 120A, and the inner sidewall 119B of the first structures 120B, i.e., is not disposed over the outer sidewall 113A of the second structure 121A, an outer sidewall 113B of the second structure 1211B, an inner sidewall 123A of the second structure 121A, and an inner sidewall 123B of the second structure 121B.

Each sub-pixel 106 includes an encapsulation layer 116. The encapsulation layer 116 may be or may correspond to a local passivation layer. The encapsulation layer 116 of a respective sub-pixel is disposed over the cathode 114 (and OLED material 112) with the encapsulation layer 116 extending under at least a portion of each of the first overhangs 109, the second overhangs 117, and along the sidewalls 111A, 111B, 113A, 113B, 119A, 119B, 123A, and 123B. The encapsulation layer 116 is disposed over the cathode 114 and extends at least to contact the cathode 114 over the sidewall 111A, 111B, 119A, and 119B of the first structure 120A and 120B in the pixel plane. In some embodiments, the encapsulation layer 116 extends to contact the sidewall 111A, 111B, 119A, and 119B of the first structures 120A and 120B. In some embodiments, the encapsulation layer 116 extends to contact the second structure 110B at an underside surface of the first overhang extension 109A, 109B, the second overhang extension 117A and 117B, and the sidewalls 113A, 113B, 123A, and 123B of the second structures 121A and 121B. In some embodiments, the encapsulation layer 116 ends at the sidewall 111A, 111B, 119A, and 119B of the first structures 120A, 120B, i.e., is not disposed over the sidewalls 113A, 113B, 123A, and 123B and the upper surface 105A and 105B of the second structures 121A and 121B. The encapsulation layer 116 includes the non-conductive inorganic material, such as the silicon-containing material. The silicon-containing material may include Si₃N₄ containing materials.

Disposing the OLED material 112, the cathode 114, and the encapsulation layer 116 over the sidewalls 111A, 111B, 113A, 113B, 119A, 119B, 123A, 123B encapsulates the overhang structures 110A, 110B of the overhangs 110. The encapsulation prevents the creation of moisture invasion paths during fabrication. Less invasion paths decrease the likelihood of moisture invasion, thus preventing deterioration of the sub-pixel circuit 100.

Each sub-pixel line may adjacent separation structures, with adjacent sub-pixels sharing the adjacent separation structures in the line plane. The separation structures are permanent to the second sub-pixel circuit 100B. The separation structures further define each sub-pixel of the sub-pixel line of the second sub-pixel circuit 100B. The separation structures are disposed over an upper surface 103 of the PS 126B.

The OLED material 112 is disposed over and in contact with the metal-containing layer 104 and the separation structure in the line plane. The cathode 114 is disposed over the OLED material 112 in the line plane. The encapsulation layer 116 is disposed over the cathode 114 in the line plane. As shown in FIG. 1D, the OLED material 112, the cathode 114, and the encapsulation layer 116 maintain continuity along the length of the line plane in order to apply current across each sub-pixel 106.

In embodiments including one or more capping layers, the capping layers are disposed between the cathode 114 and the encapsulation layer 116. E.g., a first capping layer and a second capping layer are disposed between the cathode 114 and the encapsulation layer 116. Each of the embodiments described herein may include one or more capping layers disposed between the cathode 114 and the encapsulation layer 116. The first capping layer may include an organic material. The second capping layer may include an inorganic material, such as lithium fluoride. The first capping layer and the second capping layer may be deposited by evaporation deposition.

In another embodiment, the first sub-pixel circuit 100A further includes at least a global passivation layer 120 disposed over the overhang structure 110 and the encapsulation layer 116. In yet another embodiment, the sub-pixel includes an intermediate passivation layer disposed over the overhang structures 110 of each of the sub-pixels 106, and disposed between the encapsulation layer 116 and the global passivation layer 120.

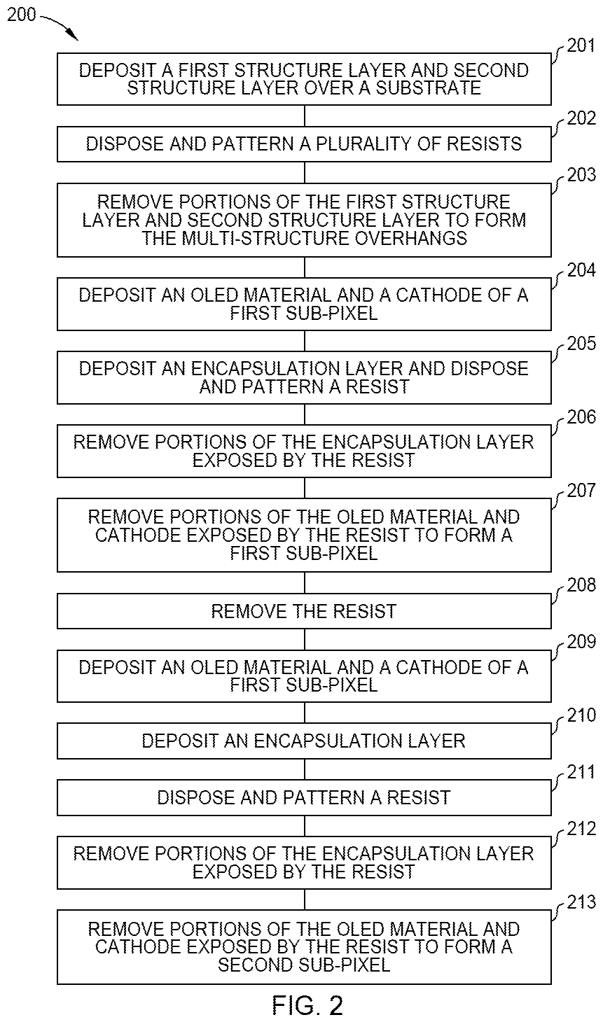

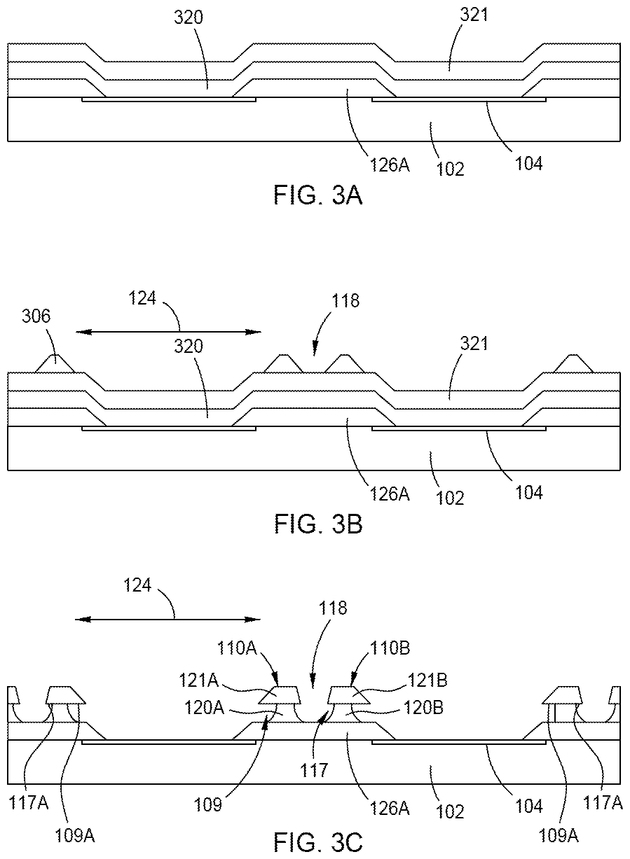

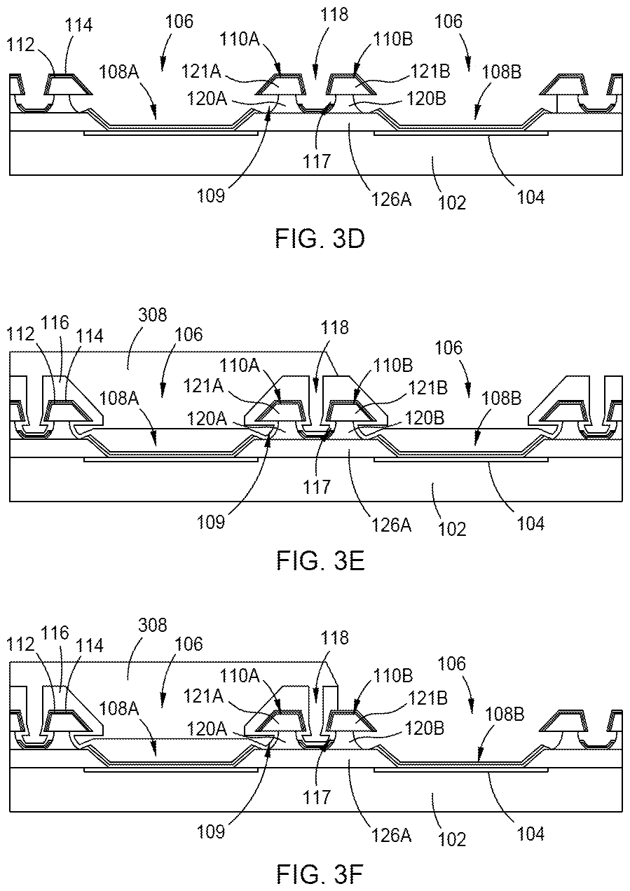

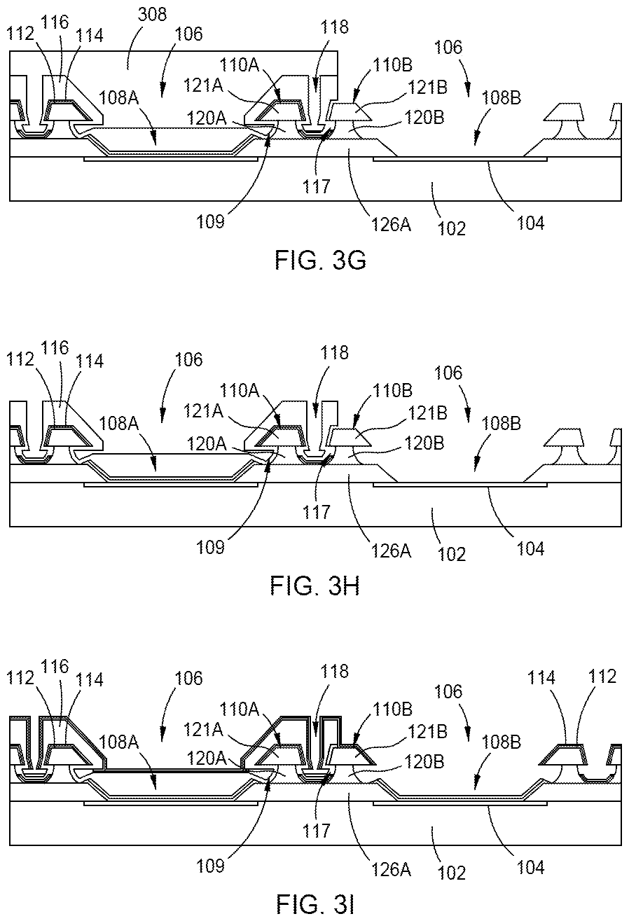

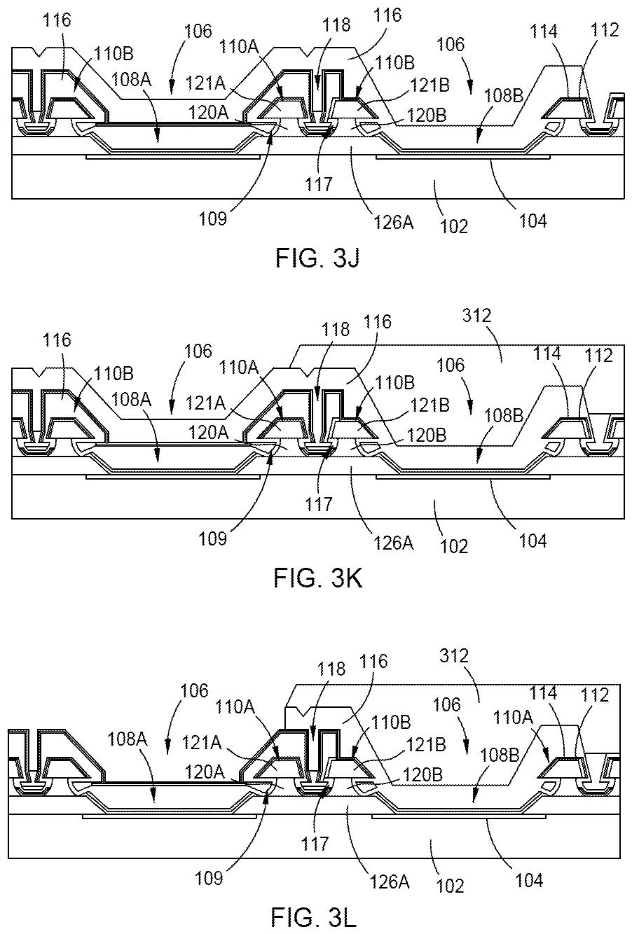

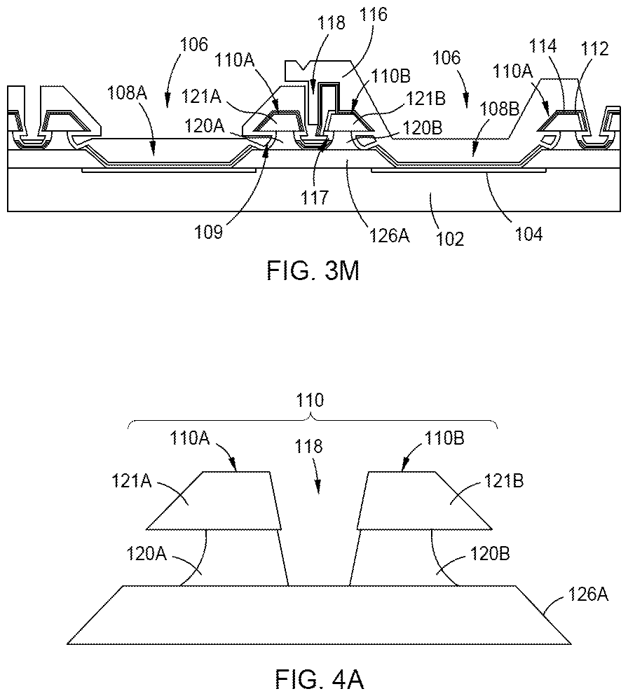

FIG. 2 is a flow a flow diagram of a method 200 for forming a sub-pixel circuit. FIGS. 3A-3M are schematic, cross-sectional views of a substrate 102 during a method 200 for forming a sub-pixel circuit. The sub-pixel circuit may be first sub-pixel circuit 100A or second sub-pixel circuit 100B.

At operation 201, as shown in FIG. 3A, a first structure layer 320 and a second structure layer 321 are deposited over the substrate 102. The first structure layer 320 is disposed over the PDL structures 126. The first structure layer 320 corresponds to a first structure 120A of a first overhang structure 110A and a first structure 120B of a second overhang structure 110B of an overhang 110. The second structure layer 321 is disposed over the first structure layer 320. The second structure layer 321 corresponds to a second structure 121A of the first overhang structure 110A and a second structure 121B of the second overhang structure 110B of the overhangs 110.

At operation 202, as shown in FIG. 3B, a plurality of resists 306 are disposed and patterned. The plurality of resists 306 are disposed over the second structure layer 321. The plurality of resists 306 are positive resists or negative resists. A positive resist includes portions of the resist, which, when exposed to electromagnetic radiation, are respectively soluble to a resist developer applied to the resist after the pattern is written into the resist using the electromagnetic radiation. A negative resist includes portions of the resist, which, when exposed to radiation, will be respectively insoluble to the resist developer applied to the resist after the pattern is written into the resist using the electromagnetic radiation. The chemical composition of the resist 306 determines whether the resist is a positive resist or a negative resist. The portion of the second structure layer 321 that has the resist 306 disposed thereon is patterned to form a pixel opening 124 of a first sub-pixel 108A and the structure gap 118. The patterning is one of a photolithography, digital lithography process, or laser ablation process.

At operation 203, as shown in FIG. 3C, portions of the second structure layer 321 and the first structure layer 320 exposed by the pixel opening 124 are removed. The second structure layer 321 may be removed by a dry etch process. The first structure layer 320 may be removed by a wet etch process. Operation 203 forms the overhangs 110 having two or more overhang structures, e.g., the first overhang structure 110A and the second overhang structure 110B. The first overhang structure 110A includes the second structure 121A formed from the second structure layer 321. The second overhang structure 110B includes the second structure 121B formed from the second structure layer 321. The first overhang structure 110A includes the first structure 120A formed from the first structure layer 320. The second overhang structure 110B includes the first structure 120B formed from the first structure layer 320. The first overhang structure 110A and the second overhang structure 110B are separated by the structure gap 118. Each overhang structure includes a first overhang 109 and a second overhang 117. The first overhang 109 of the first overhang structure 110A is defined by a first overhang extension 109A of the second structure 121A extending laterally past the upper surface 105A and an outer sidewall 111A of the first structure 120A. The first overhang 109 of the second overhang structure 110B is defined by a second overhang extension 109B of the second structure 121B extending laterally past the upper surface 105B and an outer sidewall 111B of the first structure 120B. The second overhang 117 of the first overhang structure 110A is defined by a first overhang structure inner extension 117A of the second structure 121A extending past the upper surface 105A and an inner sidewall 119A of the first structure 120A. The second overhang 117 of the second overhang structure 110B is defined by a second overhang structure inner extension 117B of the second structure 121B extending past the upper surface 105B and an inner sidewall 119B of the first structure 120B. The plurality of resists 306 are removed.

At operation 204, as shown in FIG. 3D, an OLED material 112 and a cathode 114 of the first sub-pixel 108A are deposited. The shadowing of the first overhang 109 and the second overhang 117 provides for evaporation deposition of each of the OLED material 112 and the cathode 114.

At operation 205, as shown in FIG. 3E, an encapsulation layer 116 of the first sub-pixel 108A and a resist 308 are deposited and patterned. The resist 308 is a positive resist or a negative resist. The chemical composition of the resist 308 determine whether the resist 308 is a positive resist or a negative resist. The resist 308 is patterned to protect the first sub-pixel 108A from the subsequent etching processes. The resist 308 is deposited in the structure gap 118.

At operation 206, as shown in FIG. 3F, portions of the encapsulation layer 116 exposed by the resist 308 are removed. The encapsulation layer 116 may be removed by a dry etching process. At operation 207, as shown in FIG. 3G, the portions of the OLED material 112 and the cathode 114 exposed by the resist 308 are removed. The OLED material 112 and cathode 114 may be removed by a wet etching process. The portion of the resist 308 disposed in the structure gap 118 protects the OLED material 112, cathode 114, and encapsulation layer 116 disposed over the inner sidewall 123A of the second structure 121A and the inner sidewall 119A of the first structure 120A of the first overhang structure 110A from being etched. Similarly, in the adjacent overhang 110 defining the first sub-pixel 108A, the portion of the resist 308 disposed in the structure gap 118 protects the OLED material 112, cathode 114, and encapsulation layer 116 disposed over the inner sidewall 123B of the second structure 121B and the inner sidewall 119B of the first structure 120B of the second overhang structure 110B from being etched.

At operation 208, as shown in FIG. 3H, the resist 308 is removed. Removing the resist leaves behind the first sub-pixel 108A.

At operation 209, as shown in FIG. 3I, an OLED material 112 and a cathode 114 of the second sub-pixel 108B are deposited. The shadowing of the first overhang 109 and the second overhang 117 provides for evaporation deposition of each of the OLED material 112 and the cathode 114.

At operation 210, as shown in FIG. 3J, an encapsulation layer 116 of the second sub-pixel 108B is deposited. At operation 211, shown in FIG. 3K, a resist 312 is deposited and patterned. The resist 312 is a positive resist or a negative resist. The chemical composition of the resist 312 determine whether the resist 312 is a positive resist or a negative resist. The resist 312 is patterned to protect the second sub-pixel 108B from the subsequent etching processes. The resist 312 is deposited over the structure gap 118.

At operation 212, as shown in FIG. 3L, portions of the encapsulation layer 116 exposed by the resist 312 are removed. The portions of the encapsulation layer 116 exposed by the resist 312 are the portions over which the resist was not deposited and patterned. The encapsulation layer 116 may be removed by a dry etching process.

At operation 213, as shown in FIG. 3M, the portions of the OLED material 112 and the cathode 114 exposed by the resist 312 are removed. The resist 312 is removed. The OLED material 112 and cathode 114 may be removed by a dry etching or a wet etching process. The portion of the resist 312 disposed over the structure gap 118 protects the encapsulation layer 116 disposed over the inner sidewall 123B of the second structure 121B and the inner sidewall 119B of the first structure 120B of the second overhang structure 110B from being etched. Similarly, in the adjacent overhang 110 defining the second sub-pixel 108B, the portion of the resist 312 disposed in the structure gap 118 protects the encapsulation layer 116 disposed over the inner sidewall 123A of the second structure 121A and the inner sidewall 119A of the first structure 120A of the first overhang structure 110A from being etched. Removing the resist leaves behind the second sub-pixel 108B.

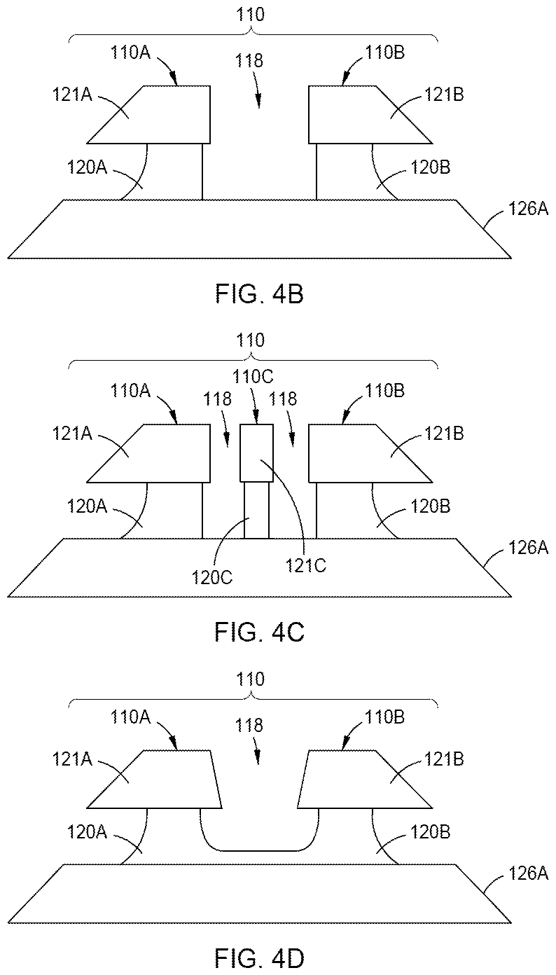

FIGS. 4A-4D are schematic, cross-sectional views of an overhang 110. FIG. 4A is a schematic, cross-sectional view of an overhang 110 having the first overhangs 109 and an angled etch. The first structure 120A, 120B and the second structure 121A, 121B may both be etched using a dry etching process or a wet etching process to minimize lateral etching. The use of the dry etching for both the first structure 120A, 120B and the second structure 121A, 121B increases process flexibility while preventing the creation of moisture invasion paths.

FIG. 4B is a schematic, cross-sectional view of an overhang 110 having the first overhangs 109 and a parallel etch. The first structure 120A, 120B and the second structure 121A, 121B may both be etched using a dry etching process or a wet etching process to minimize lateral etching. The use of the dry etching for both the first structure 120A, 120B and the second structure 121A, 121B increases process flexibility while preventing the creation of moisture invasion paths.

FIG. 4C is a schematic, cross-sectional view of an overhang 110 having a third overhang structure 110C. The third overhang structure includes a first structure 120C and a second structure 121C. Additional overhang structures further prevents the creation of moisture invasion paths due to the more complicated structure. The third overhang structure 110C may be shared with other sub-pixels 106 to improve the functionality of the sub-pixel circuit 100.

FIG. 4D is a schematic, cross-sectional view of an overhang 110 having the first overhangs 109 and second overhangs 117 and a partial first structure 120A etch.

The etch selectivity between the materials of the second structure layer 321 corresponding to the second structure 121A, 121B and the first structure layer 320 corresponding to the first structure 120A, 120B provide for variations in the shape of the overhangs 110.

While the foregoing is directed to embodiments of the present disclosure, other and further embodiments of the disclosure may be devised without departing from the basic scope thereof, and the scope thereof is determined by the claims that follow.

What is claimed is:

1. A device,
a substrate;
and
a plurality of sub-pixels, each sub-pixel comprising:
adjacent overhangs disposed over the substrate, each overhang comprising:
two or more overhang structures, the overhang structures comprising:
a first overhang defined by a first overhang structure outer extension of a second structure extending laterally past a first structure, the first structure disposed over the substrate, and the second structure disposed over the first structure, wherein the second structure of a first overhang structure is separated from the second structure of a second overhang structure by a structure gap;
an organic light emitting diode (OLED) material disposed over an anode; and
a cathode disposed over the OLED material.

2. The device of claim 1, wherein the OLED material and the cathode are disposed over an upper surface of the second structure.

3. The device of claim 1, wherein the first overhang is further defined by the first overhang structure outer extension extending laterally past an outer sidewall of the first structure.

4. The device of claim 3, further comprising a second overhang defined by a first overhang structure inner extension extending laterally past an inner sidewall of the first structure.

5. The device of claim 4, wherein an encapsulation layer is disposed over and extends under at least a portion of the first overhang.

6. The device of claim 5, wherein the encapsulation layer is disposed over the inner sidewall of the first structure and the outer sidewall of the first structure.

7. The device of claim 6, wherein the encapsulation layer is disposed over the outer sidewall and inner sidewall of the second structure.

8. The device of claim 1, wherein the first structure of the first overhang is separated from the first structure of the second overhang by the structure gap.

9. The device of claim 1, wherein the second structure include an inorganic material.

10. The device of claim 1, wherein the first structure s includes a conductive inorganic material.

11. The device of claim 10, wherein the conductive inorganic material includes copper, titanium, aluminum, molybdenum, silver, indium tin oxide, indium zinc oxide, or combinations thereof.

12. The device of claim 1, further comprising a third overhang structure separated from the first overhang structure and the second overhang structure.

13. A method of making a device, comprising:
depositing a first structure layer and a second structure layer over a substrate;
depositing and patterning a plurality of first resists over the second structure layer;
removing a portion of the second structure layer and the first structure layer to form an overhang, the overhang having two or more overhang structures separated by a structure gap comprising a second structure formed from the second structure layer disposed over a first structure formed from the first structure layer;
depositing an organic light emitting diode (OLED) material, a cathode, and an encapsulation layer of a first sub-pixel over the overhang;
depositing and patterning a second resist over the first sub-pixel; and
removing a portion of the encapsulation layer, the cathode, and the OLED material.

14. The method of claim 13, further comprising:
depositing an organic light emitting diode (OLED) material, a cathode, and an encapsulation layer of a second sub-pixel over the overhang;
depositing and patterning a third resist over the second sub-pixel; and
removing a portion of the encapsulation layer, cathode, and OLED material.

15. The method of claim 13, wherein the overhang structures comprise:
a first overhang defined by a first overhang structure outer extension of a second structure extending laterally past a first structure; and
a second overhang defined by a first overhang structure inner extension extending laterally past the first structure.

16. The method of claim 15, wherein the first overhang is defined by the first overhang structure outer extension extending laterally past an outer sidewall of the first structure and the second overhang is defined by a first overhang structure inner extension extending laterally past an inner sidewall of the first structure.

17. A device,
a substrate;
and
a plurality of sub-pixels, each sub-pixel comprising:
adjacent overhangs disposed over the substrate, each overhang comprising:
two or more overhang structures, the overhang structures comprising:
a first overhang defined by a first overhang structure outer extension of a second structure extending laterally past an upper surface and an outer sidewall of a first structure; and
a second overhang defined by a first overhang structure inner extension extending laterally past the upper surface and an inner sidewall of the first structure, the first structure disposed over the substrate, and the second structure disposed over the first structure, wherein a first overhang structure is separated from a second overhang structure by a structure gap;
an organic light emitting diode (OLED) material disposed over an anode; and
a cathode disposed over the OLED material.

18. The device of claim 17, further comprising a third overhang structure separated from the first overhang structure and the second overhang structure.

19. The device of claim 17, wherein an encapsulation layer is disposed over and extends under at least a portion of the first overhang and the second overhang.

20. The device of claim 19, wherein the encapsulation layer is disposed over the inner sidewall of the first structure, the outer sidewall of the first structure, the outer sidewall of the second structure, and inner sidewall of the second structure.
